(19) United States
(12) Patent Application Publication
(10) Pub. No.: US 2026/0052723 A1
(43) Pub. Date: Feb. 19, 2026

(54) FinFET WITH RECESSED TRENCH ISOLATIONS AT SIDEWALLS OF FIN

(71) Applicant: GlobalFoundries U.S. Inc., Malta, NY (US)

(72) Inventors: Hong Yu, Clifton Park, NY (US); Vitor A. Vulcano Rossi, Saratoga Springs, NY (US); Kaustubh Shanbhag, Slingerlands, NY (US); Tamilmani Ethirajan, Albany, NY (US)

(21) Appl. No.: 18/805,744

(22) Filed: Aug. 15, 2024

(51) Int. Cl. H01L 29/78; H01L 21/762; H01L 29/66

(52) U.S. Cl. CPC H10D 30/62; H01L 21/76224; H10D 30/65; H10D 30/024

(57) ABSTRACT

A structure for a FinFET, a FinFET and an LDMOS device are disclosed. The structures include a trench isolation adjacent a semiconductor fin and configured to increase a height of the semiconductor fin without increasing the footprint. The fin has junction and gate regions, and the trench isolation is adjacent a lower region the fin. The FinFET includes a first recess in the trench isolation adjacent the gate region of the fin, and a second recess in the trench isolation adjacent the junction region of the fin. The first recess is at least partially filled with a high dielectric constant (high-K) layer and a gate metal, and the second recess is at least partially filled with a low dielectric constant (low-K) layer. The trench isolation includes an upper portion and a lower portion that include materials of different compositions, e.g., a dopant in the upper portion.

### BACKGROUND

The present disclosure relates to field effect transistors (FETs) and, more particularly, to a fin-type FET having recessed trench isolations at sidewalls of the semiconductor fin.

Fin-type field effect transistors (FinFETs) are popular transistors used in integrated circuits. FinFETs include a semiconductor fin extending from a substrate. Source and drain regions are spaced within the semiconductor fin and a gate is provided over the fin to create a gate region (including at least a channel region) thereunder between the source/drain regions. Dielectric fills a space between adjacent semiconductor fins to form trench isolations that electrically isolate the FinFETs. The height of the semiconductor fin above the adjacent trench isolations in a FinFET determines a distance provided by the gate extending over the semiconductor fin and, hence, a width of a gate region of the FinFET. One challenge with FinFET formation is maintaining a semiconductor fin height above the trench isolations. As the height of the semiconductor fin decreases, it also decreases the gate region width and negatively impacts FinFET performance capabilities. The shorter fin height also increases sub-fin electrostatics for devices that have both lateral and vertical current flow from drain to source, such as FinFETs in laterally-diffused metal-oxide semiconductor (LDMOS) devices.

### SUMMARY

All aspects, examples and features mentioned below can be combined in any technically possible way.

An aspect of the disclosure provides a fin-type field effect transistor (FinFET), comprising: a semiconductor fin having a junction region therein and a gate region therein; a trench isolation adjacent a lower region of the semiconductor fin; a first recess in the trench isolation adjacent the gate region of the semiconductor fin, the first recess at least partially filled with a high dielectric constant (high-K) layer and a gate metal; and a second recess in the trench isolation adjacent the junction region of the semiconductor fin, the second recess at least partially filled with a low dielectric constant (low-K) layer.

An aspect of the disclosure provides a structure for a fin-type field effect transistor (FinFET), comprising: a trench isolation adjacent a lower region of a semiconductor fin, the trench isolation including an upper portion and a lower portion, wherein the upper portion and the lower portion include materials of different compositions.

An aspect of the disclosure provides a laterally-diffused metal-oxide semiconductor (LDMOS) device, comprising: a junction region including a first source/drain region and a second source/drain region in a semiconductor fin; a first trench isolation between the first and second source/drain regions in the semiconductor fin; a first doping region about the first source/drain region, the first doping region defining a gate region in the semiconductor fin; a second doping region about the second source/drain region, the second doping region defining a drain extension in the semiconductor fin; a gate over the gate region and the drain extension, the gate including a high dielectric constant (high-K) layer and a gate metal; a second trench isolation adjacent a lower region of the semiconductor fin adjacent the gate region; a first recess in the second trench isolation adjacent the gate region, the first recess at least partially filled with the high-K layer and the gate metal; and a second recess in the second trench isolation adjacent the junction region of the semiconductor fin, the second recess at least partially filled with a low dielectric constant (low-K) layer.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1A shows a cross-sectional view of steps of a method, according to embodiments of the disclosure;

FIG. 1B shows a perspective view of an LDMOS device, according to embodiments of the disclosure;

FIG. 2 shows a cross-sectional view of steps of a method, according to embodiments of the disclosure;

FIG. 3 shows a cross-sectional view of steps of a method, according to embodiments of the disclosure;

FIG. 4A shows a cross-sectional view of steps of a method, according to embodiments of the disclosure;

FIG. 4B shows a cross-sectional view of steps of a method, according to other embodiments of the disclosure;

FIG. 5 shows a cross-sectional view of steps of a method, according to embodiments of the disclosure;

FIGS. 6A-E show cross-sectional views of steps of a method along view line 6-6 in FIG. 1B and with FIG. 6E showing a junction region of a structure and a FinFET, according to embodiments of the disclosure; and

FIGS. 7A-D show cross-sectional views of steps of a method along view line 7-7 in FIG. 1B and with FIG. 7D showing a gate region of a structure and a FinFET, according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative. It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

In addition, several descriptive terms may be used regularly herein, as described below. The terms “first,” “second,” and “third,” may be used interchangeably to distinguish one component from another and are not intended to signify location or importance of the individual components.

Embodiments of the disclosure include a structure, a fin-type field effect transistor (FinFET) and a laterally-diffused metal-oxide semiconductor (LDMOS) device. The various structures include a trench isolation adjacent a lower region of a semiconductor fin with the trench isolation configured to constructively increase a height of the semiconductor fin without increasing the footprint. The FinFET includes a semiconductor fin having a junction region therein and a gate region (including at least a channel region) therein, and the trench isolation is adjacent a lower region of the semiconductor fin. The FinFET also includes a gate recess in the trench isolation adjacent the gate region of the semiconductor fin, and a junction recess in the trench isolation adjacent the junction region of the semiconductor fin. The gate recess is at least partially filled with a high dielectric constant (high-K) layer and a gate metal, and the junction recess is at least partially filled with a low dielectric constant (low-K) layer. The trench isolation is adjacent a lower region of a semiconductor fin and may include an upper portion and a lower portion that include materials of different compositions, e.g., a dopant in the upper portion but not the lower portion. The various structures improve device performance by elongating a width of the gate region without increasing a footprint of the structure. The structures also reduce sub-fin electrostatic for devices that have both lateral and vertical current flow from drain to source, such as FinFET LDMOS. LDMOS devices also exhibit increased off-state response due to improved gate control at a base of the fin.

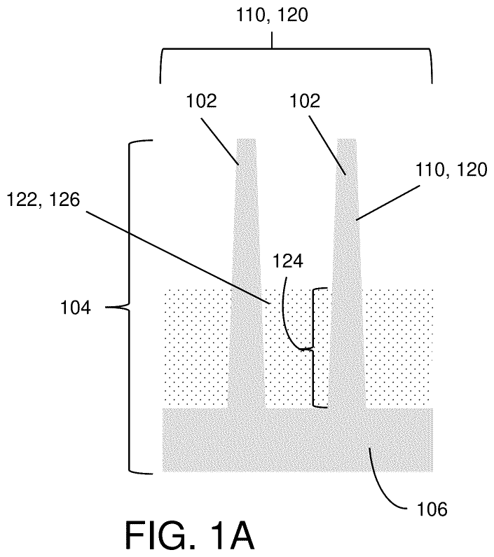

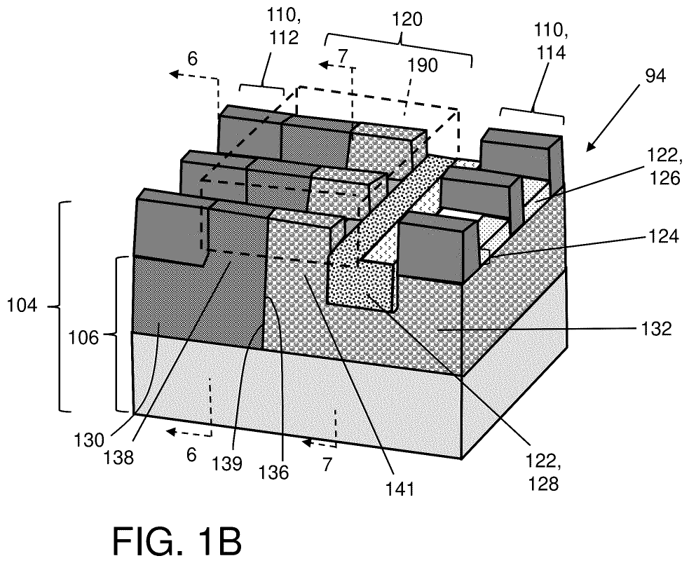

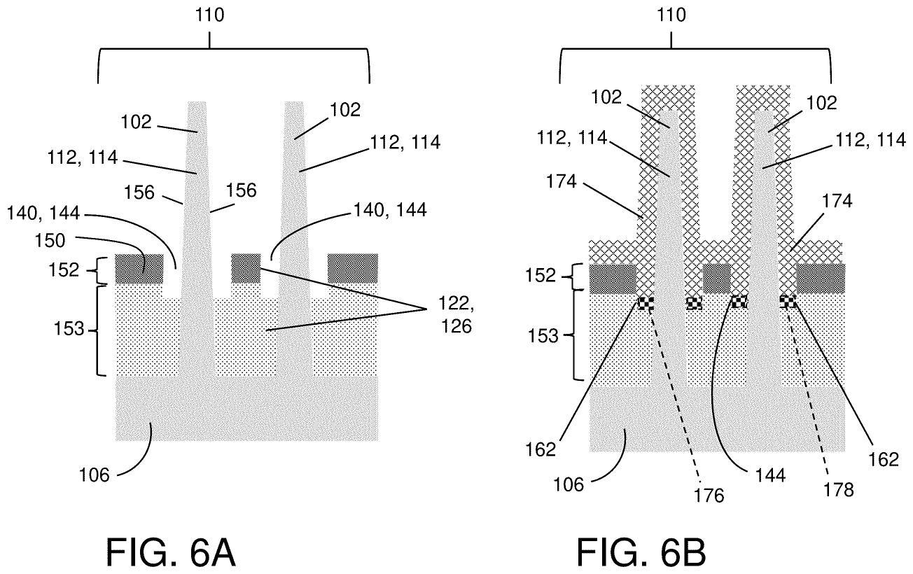

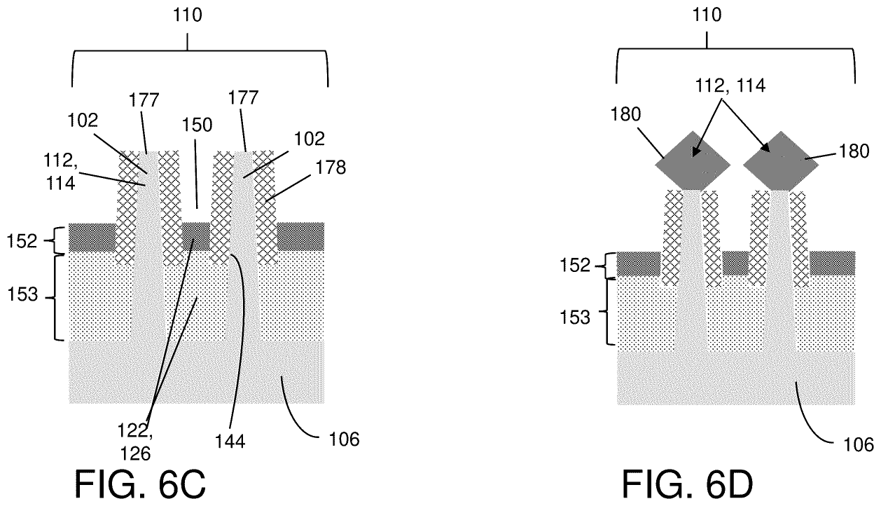

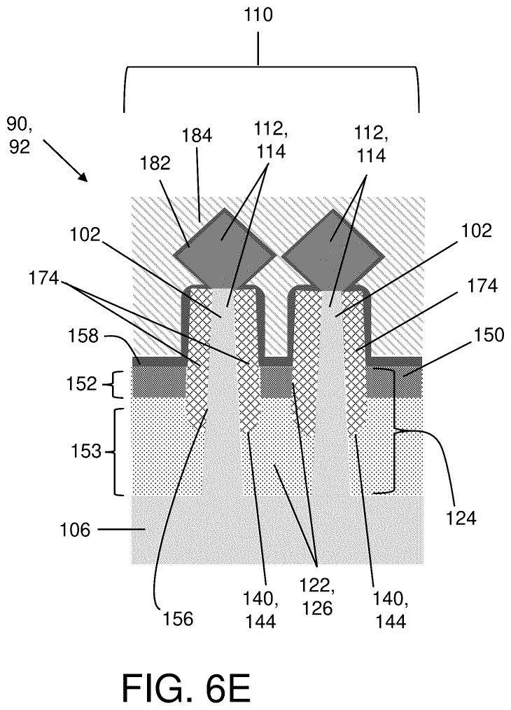

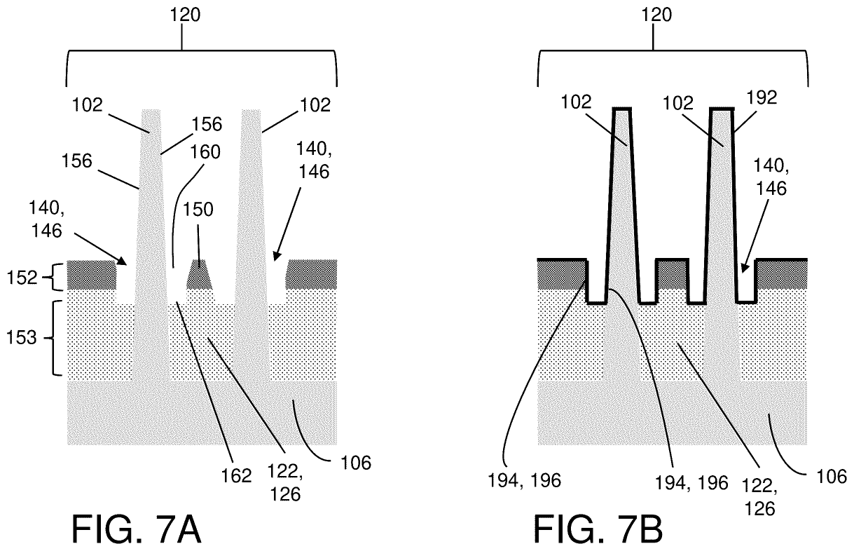

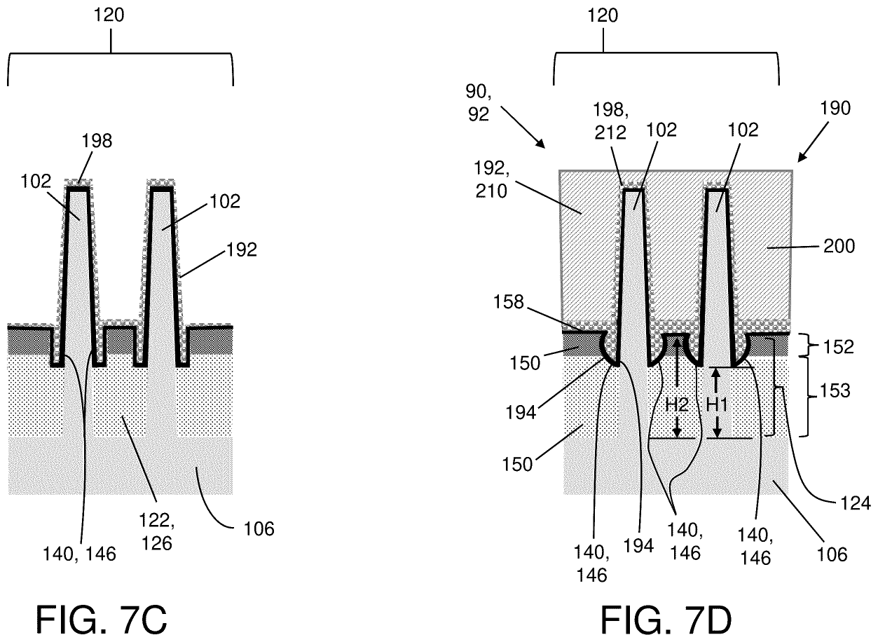

FIGS. 1A and 2-7D show cross-sectional views of a method of forming a structure 90 (FIGS. 6E and 7D) for a FinFET, according to embodiments of the disclosure. FIG. 1B shows a perspective view of the structure in the form of a laterally-diffused metal-oxide semiconductor (LDMOS) device 94, and also provides view lines for perspective on locations along semiconductor fins 102 described with the other drawings. Note, FIG. 1B does not include any replacement metal gate (RMG) or middle-of-line structures for clarity purposes. FIGS. 1A-B and 2-5 show steps of the method applied across a longitudinal extent of semiconductor fins 102;

FIGS. 6A-E show steps of the method applied in a junction region 110 of semiconductor fins 102 along view line 6-6 in FIG. 1B; and FIGS. 7A-D shows steps of the method applied in a gate region 120 of semiconductor fins 102 along view line 7-7 in FIG. 1B. As will be described herein, in certain embodiments, structure 90 may be part of and/or constitute a fin-type field effect transistor (FinFET) 92 (FIG. 7D), and, in other embodiments, structure 90 may be part of and/or constitute LDMOS device 94 (FIG. 1B).

FIG. 1A shows forming a semiconductor fin 102. Semiconductor fin 102 can be formed using any now known or later semiconductor fin fabrication techniques, e.g., etching semiconductor fins 102 from a semiconductor substrate 106. Semiconductor fin 102 may be part of a semiconductor body 104 that includes semiconductor fin 102 over a (bulk) semiconductor substrate 106. Semiconductor body 104 may include but is not limited to silicon, germanium, silicon germanium, silicon carbide, and those consisting essentially of one or more III-V compound semiconductors. Other suitable substrates include II-VI compound semiconductors. A portion or entire semiconductor fin 102 and/or substrate 106 may be strained.

Semiconductor substrate 106 may include a dopant. In one embodiment, the dopant may include a p-type dopant, which may include but is not limited to: boron (B), indium (In) and gallium (Ga). P-type dopants are elements introduced to semiconductor to generate a free hole by “accepting” electron from semiconductor atom and “releasing” the hole at the same time. The dopant may be introduced to semiconductor substrate 106 in any now known or later developed fashion, e.g., in-situ doping during formation, or ion implanting. Usually in doping, a dopant, a dosage and an energy level are specified and/or a resulting doping level may be specified. A dosage may be specified in the number of atoms per square centimeter (cm²) and an energy level (specified in keV, kilo-electron-volts), resulting in a doping level (concentration in the substrate) of a number of atoms per cubic centimeter (cm³). As shown in FIG. 1B, semiconductor fin 102 includes a junction region 110 (i.e., including a source/drain region 112 and a source/drain region 114 at opposite ends of fin 102) and a gate region 120 therebetween. Note, region 112 is shown as a source region 112 and region 114 is shown as a drain region; it is recognized that their locations can be switched. As understood in the field, the regions 110, 120 are located at different longitudinal locations along semiconductor fin 102

FIG. 1A shows forming a trench isolation(s) 122 adjacent a lower region 124 of semiconductor fins 102 (hereafter “fin 102” or “fins 102” for brevity). Trench isolation(s) 122 may include a first trench isolation 126 between adjacent fins 102. As shown in FIG. 1B, trench isolation(s) 122 may also include a second trench isolation 128 between source region 112 and drain region 114 in fin 102 (and, more particularly, within fin 102 between gate region 120, as discussed below, and drain region 114, when structure 90 (FIGS. 6E, 7D) is part of an LDMOS device 94 (FIGS. 6E, 7D). While two trench isolations will be described herein, it will be recognized that they can be connected so they are part of a single structure. Trench isolation(s) 122 may take any form of an isolating structure or material, but typically includes a shallow trench isolation (STI). Trench isolation(s) 122 may be formed using any now known or later developed semiconductor fabrication technique. Generally, a trench(es) is/are either etched into a space between fins or is already existing between fins 102. The trench(es) is/are filled with an insulating material, such as silicon oxide, to isolate one region of semiconductor body 104 from an adjacent region of the body. Trench isolation(s) 122 may be formed of any currently-known or later developed substance for providing electrical insulation, and as examples may include but are not limited to: silicon oxide, silicon nitride, fluorinated silicon oxide (FSG), or layers thereof. Trench isolations 126, 128 may have different depths depending on location and function, e.g., second trench isolation 128 for LDMOS device 94 (FIG. 1B) may be deeper than first trench isolation 126 between fins 102 (FIG. 1A). For FinFETs 92 (FIGS. 6E, 7D) that are not LDMOS devices 94, second trench isolation 128 is omitted.

FIG. 1B also shows optionally forming various doping regions in semiconductor body 104. While shown relative to LDMOS device 94, it will be recognized that the doping regions may be used in other forms of FinFETs 92 (FIGS. 6E, 7D) or they may be omitted. FIG. 1B shows forming a first doping region 130 about a (to-be-formed) source region 112 in fin 102, and a second doping region 132 about a (to-be-formed) drain region 114 in fin 102. Doping regions 130, 132 and source/drain regions 112, 114 may be formed using any now known or later developed semiconductor fabrication technique. For example, source/drain regions 112, 114 may be formed by mask-directed doping by ion implantation followed by an anneal to drive in the dopants. Source/drain regions 112, 114 may be doped with an n-type dopant. N-type dopants may include but are not limited to: phosphorous (P), arsenic (As), or antimony (Sb). N-type is an element introduced to semiconductor to generate free electrons by “donating” electrons to the semiconductor. First doping region 130 may take the form of a p-type doped well (hereafter “p-well”) 130. The p-type dopant may be the same as semiconductor substrate 106, but with a higher dopant concentration. P-well 130 may be formed using any now known or later developed semiconductor fabrication technique, e.g., mask-directed ion implantation prior to formation of first source/drain region 112, e.g., a source region 112. For an LDMOS device 94, second doping region 132 is about second source/drain region 114 (e.g., a drain region 114), and second trench isolation 128 is within second doping region 132. Second doping region 132 may be between drain region 114 and second trench isolation 128, although this is not necessary in all cases. Second doping region 132 may take the form of an n-type doped well, or n-well (hereafter “n-well”) 132. The n-type dopant may be the same as source/drain regions 112, 114, but with a lower dopant concentration. N-well 132 may be formed using any now known or later developed semiconductor fabrication technique, e.g., mask-directed ion implantation prior to formation of drain region 114. As understood in the field, in an LDMOS device 94, a space between source region 112 and an edge 136 of p-well 130 defines a channel region 138 within gate region 120 of the device; and a space between second trench isolation 128 and edge 139 of n-well 132 defines a drain extension 141 within gate region 120 of the device. While edges 136, 139 are shown as co-linear, that is not necessary in all instances. As noted, for FinFETs 92 (FIGS. 6E, 7D) that are not LDMOS devices 94, second trench isolation 128 is omitted.

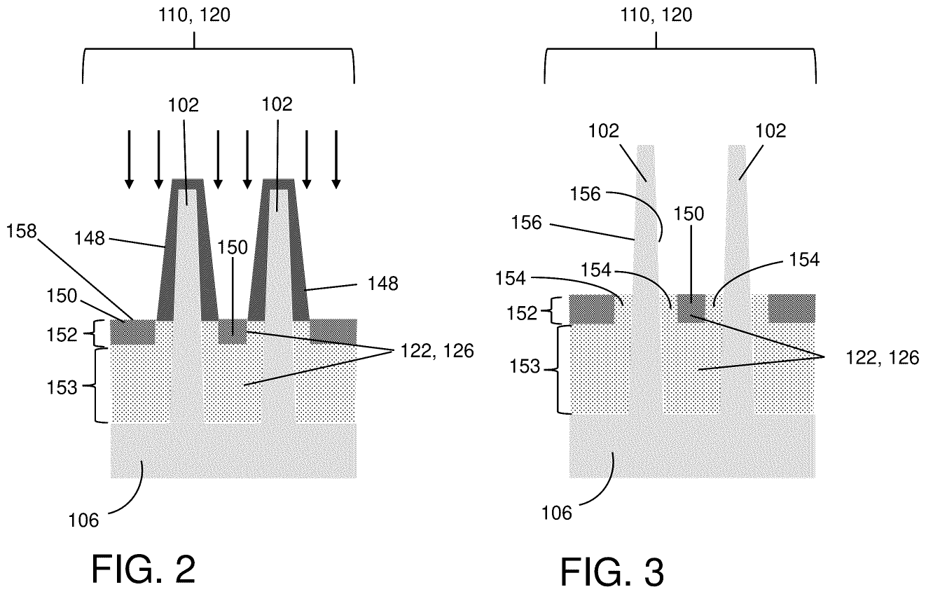

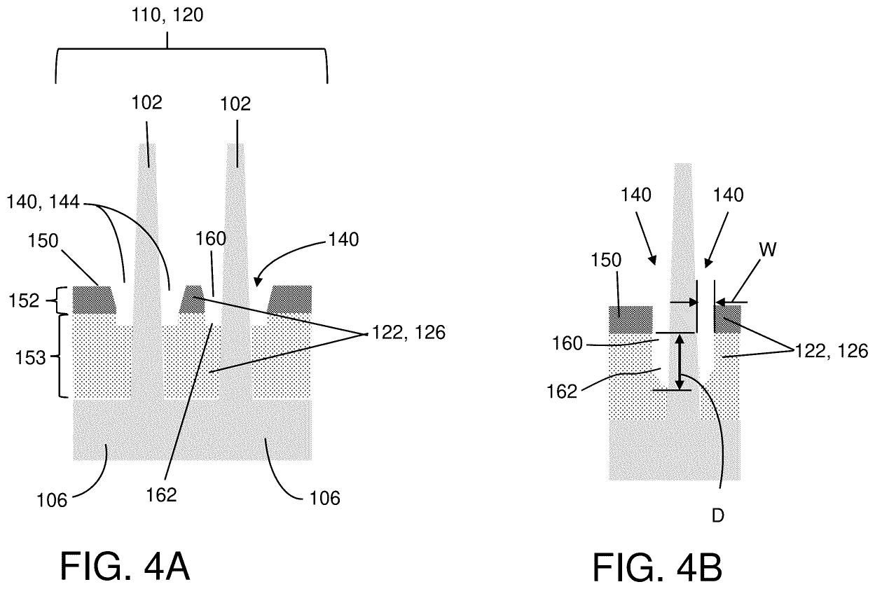

FIGS. 2-5 show cross-sectional views of forming one or more recesses 140 in trench isolation 126 adjacent fin 102 according to embodiments of the disclosure. Note, FIG. 4A shows a cross-sectional view of recess 140 in first trench isolation 126 adjacent fin 102 according to certain embodiments of the disclosure, and FIG. 4B shows an enlarged cross-sectional view of recess 140 in first trench isolation 126 adjacent fin 102 according to other embodiments of the disclosure. As noted, the cross-sectional views of FIGS. 2-5 show processing of fin(s) 102 in both gate region 120 and junction region 110, i.e., the processing in FIGS. 2-5 is applied across the wafer and along a length of fin(s) 102. As noted, FIGS. 6A-E show subsequent processing in just junction region 110 along view line 6-6 in FIG. 1B, and FIGS. 7A-D show subsequent processing in just gate region 120 along view line 7-7 in FIG. 1B. As shown FIGS. 6A and 7A, and as will be further described herein, forming recess(es) 140 may include, as shown in FIG. 6A, forming one or more recesses 144 in first trench isolation 126 adjacent junction region 110 of fin(s) 102 and, as shown in FIG. 7A, forming one or more recesses 146 in first trench isolation 126 adjacent gate region 120 of fin(s) 102. For differentiation purposes, junction recess(es) 144 (FIGS. 6A-D) in junction region 110 will be referenced herein as “junction recess(es) 144” and recess(es) 146 (FIGS. 7A-D) in gate region 120 will be referenced herein as “gate recess(es) 146”. Collectively, junction and gate recesses 144, 146 may be referenced as “recess(es) 140”.

Referring to FIG. 2, the recess forming step may include forming a spacer 148 about fin(s) 102 and performing a hardening implant to form a hardened portion 150 in an upper portion 152 of first trench isolation 126. Spacer(s) 148 may be formed by depositing a spacer material, e.g., a nitride, by any appropriate deposition technique, e.g., chemical vapor deposition, and conducting a selective etch, e.g., a reactive ion etch. Spacers 148 can be precisely dimensioned in this manner to laterally extend from fin(s) 102 to a desired dimension. As the techniques of forming spacers 148 are otherwise well known in the field, no further details are necessary. The hardening implant may include implanting any species capable of hardening the material of first trench isolation 126. For example, where first trench isolation 126 includes silicon oxide, the dopant may include helium or silicon. Other dopants are also possible. The depth of implant is relatively shallow, e.g., 1-5 nanometers. As a result of the hardening implant, first trench isolation 126 includes an upper portion 152 and a lower portion 153, and upper portion 152 and lower portion 153 include materials of different compositions. More particularly, upper portion 152 includes a dopant therein and lower portion 153 is devoid of the dopant. Due to the presence of hardened portion 150, upper portion 152 of trench isolation 126 experiences very little etching and retains an upper surface 158 that is planar, i.e., it is flat with no dips or other irregularities.

FIG. 3 shows removal of spacer(s) 148 (FIG. 2) using any appropriate stripping process, e.g., for nitride. Spacer(s) 148 removal exposes unhardened portions 154 of first trench isolation 126 adjacent sidewalls 156 of fin(s) 102, i.e., between hardened portions 150 and sidewalls 156 of fin(s) 102.

FIG. 4A shows etching first trench isolation 126 to form recess(es) 140. The etch may include, for example, a plasma-based etch such as a reactive ion etch (RIE) or other etch chemistry appropriate for the material of first trench isolation 126. Here, hardened portions 150 are more etch resistant and remain in place, while unhardened portions 154 (FIG. 3) are removed, creating recess(es) 140. As shown in FIG. 4A, recess(es) 140 may be narrower near a bottom thereof than at a top thereof. That is, an upper portion 160 of recess 140 is wider than a lower portion 162 of recess 140. FIG. 4B shows an enlarged cross-sectional view of recesses 140 according to other embodiments of the disclosure. In FIG. 4B, upper portion 160 of recess(es) 140 is wider than lower portion 162 of recess(es) 140 and lower portion 162 may also be slightly rounded. Other shapes are also possible. Dimensions of recess(es) 140 can be user defined and may depend on various fin 102 and first trench isolation 126 attributes such as but not limited to materials used, etching attributes (power, duration, etc.), hardened portion 150 attributes (dopant, depth, dopant concentration, etc.), among other factors. In one non-limiting example, for a 47-nanometer pitch in fins 102, recess 140 may have a maximum width W (FIG. 4B) in a range of 1 to 10 nanometers and a maximum depth D (FIG. 4B) of 1 to 20 nanometers. Other dimensions are also possible.

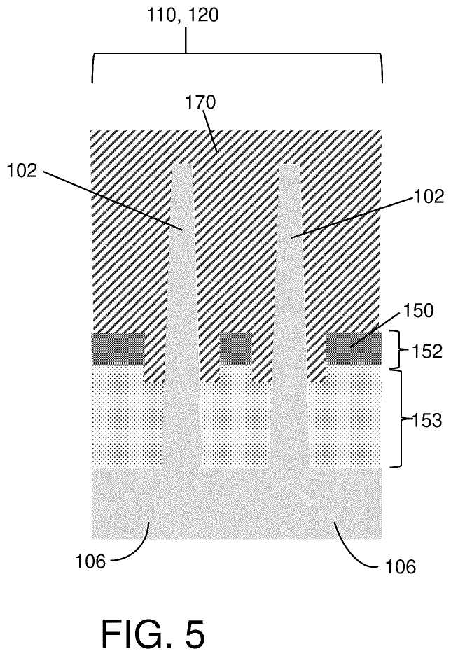

FIG. 5 shows forming a fill material 170 over fin(s) 102. Fill material 170 may include any now known or later developed sacrificial fill material, such as those typically used in a replacement metal gate (RMG) process. Fill material 170 may include but is not limited to polysilicon or amorphous silicon. Other fill materials are also possible. The RMG process may include any now known or later developed RMG techniques, and therefore will not be described in great detail herein.

FIGS. 6A-E show subsequent processing in junction region 110 of fin(s) 102, e.g., along view line 6-6 in FIG. 1B. Here, processing occurs relative to junction recess 144 in junction region 110 of fin(s) 102. More particularly, FIGS. 6A-E show additional steps of forming source/drain regions 112, 114 in junction region 110. As will be described, forming source/drain regions 112, 114 includes at least partially filling junction recess 144 with a low dielectric constant (low-K) layer 174.

FIG. 6A shows removing fill material 170 (FIG. 5) from junction region 110. Fill material 170 may be removed using any now known or later developed process. In one example, a mask (not shown) is deposited and patterned to expose the desired areas of junction region 110, fill material 170 is etched away, and then the mask is removed. In this case, fill material 170 may be removed, for example, by a RIE or other etch chemistry appropriate for fill material 170. The removal of fill material 170 re-opens junction recess(es) 144 in first trench isolation 126 in junction region 110 of fin(s) 102.

FIG. 6B shows forming layer(s) that fill junction recess(es) 144. At least a portion of junction recess 144 is filled with (low-K) layer 174. Low-K layer 174 may include any dielectric material used in integrated circuits having a dielectric constant less than 3.9, such as but not limited to: silicon oxide; carbon-doped silicon oxide; FSG; organic polymeric thermoset materials; silicon oxycarbide; SiCOH dielectrics; and spin-on glasses. The material in junction recess(es) 144 may include one or more layers of material. In one embodiment, shown by dashed lines in FIG. 6B, the layers may include forming a material 176 in lower portion 162 of junction recess 144 having a higher thermal conductivity than low-K layer 174 that is formed thereover. Material 176 may include any now known or later developed material having a higher thermal conductivity and similar electrical isolation properties as low-K layer 174, such as but not limited to aluminum nitride and sapphire. Material 176 can also be omitted and only low-K layer 174 used. As shown in FIG. 6B, low-K layer 174 also covers fin(s) 102.

FIG. 6C shows a recessing etch of low-K layer 174 that removes excess material and removes a top of fin(s) 102 to form spacers 178 adjacent fin(s) 102 and leaves an upper surface 177 of fin(s) 102 exposed. The recess etch may include, for example, a RIE. The etching does not re-open junction recess(es) 144 (FIG. 6A) due to the thickness of low-K layer 174. In one non-limiting example, where junction recess(es) 144 have a maximum width of 10 nanometers, low-K layer 174 may have a thickness of 12 to 15 nanometers, preventing any re-opening of junction recess(es) 144 (FIG. 6A).

FIG. 6D shows forming raised source/drain regions 180 for source/drain regions 112, 114 on fin(s) 102, and FIG. 6E shows forming an etch stop layer 182, and an interlayer dielectric (ILD) 184 over junction region 110. Raised source/drain regions 180 may be formed using any now known or later developed technique such as epitaxial growth from exposed upper surfaces 177 (FIG. 6C) of fin(s) 102. Etch stop layer 182 may include any now known or later developed etch stop material, such as but not limited to silicon nitride and/or silicon oxynitride, and may be deposited using any appropriate deposition technique, e.g., chemical vapor deposition. ILD 184 may include any now known or later developed dielectric used for ILDs in integrated circuits such as those materials listed for low-K layer 174, and may be deposited using any appropriate technique, e.g., CVD.

FIGS. 7A-E show subsequent processing in gate region 120 of fin(s) 102, e.g., along view line 7-7 in FIG. 1B. More particularly, FIGS. 7A-D show forming a gate 190 (FIG. 7D) over gate region 120 by forming a high-k layer 192 and a gate metal 198. As will be described, gate 190 forming at least partially fills gate recess(es) 146 with high-K layer 192 and gate metal 198.

FIG. 7A shows removing fill material 170 (FIG. 5) from gate region 120. Fill material 170 may be removed using any now known or later developed process. In one example, a mask (not shown) is deposited and patterned to expose the desired areas of gate region 120, fill material 170 is etched away, and then the mask is removed. In gate region 120, fill material 170 is removed where a gate(s) 190 (FIG. 7D) is/are desired to be formed to create channel regions in fin(s) 102, such as channel region 138 (FIG. 1B) in fin(s) 102 for an LDMOS device 94 (FIG. 1B). In this case, fill material 170 may be removed, for example, by a RIE or other etch chemistry appropriate for fill material 170. The removal of fill material 170 re-opens gate recess(es) 146 in first trench isolation 126 in gate region 120.

FIGS. 7B-C show forming layer(s) that fill gate recess(es) 146. At least a portion of gate recess(es) 146 is filled with a high-dielectric constant (high-K) layer 192. High-K layer 192 may include any dielectric material used in integrated circuits having a dielectric constant greater than the dielectric constant of silicon oxide (i.e., greater than 3.9). High-K layer 192 acts as a gate dielectric layer for gate 190 (FIG. 7D). Illustrative high-K dielectric materials include but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). As shown in FIG. 7B, high-K layer 192 may be on opposing sidewalls 194 of gate recess(es) 146, i.e., on sidewall 156 of fin 102 and on sidewall 196 of first trench isolation 126. High-K layer 192 may be deposited using any appropriate deposition technique, e.g., atomic layer deposition (ALD). As illustrated in FIG. 7B, high-K layer 192 does not completely fill gate recess(es) 146.

FIG. 7C shows forming gate metal 198 over high-K layer 192. In many cases, gate metal 198 completes the filling of gate recess(es) 146, such that high-K layer 192 and gate metal 198 fully fill gate recess(es) 146. Consequently, gate metal 198 may be between high-K layer 192 on opposing sidewalls 194 of gate recess 146, i.e., between sidewall 156 of fin 102 and sidewall 196 of first trench isolation 126. Gate metal 198 may include one or more work function (WF) metal or metal alloy layers. The WF metal or metal alloy layer(s) can be selected to achieve the optimal WF depending upon the conductivity type of the FET (i.e., optimal NFET WF for an NFET or optimal PFET WF for a PFET). Those skilled in the art will further recognize that the optimal WF for a gate conductor of an NFET will be, for example, between 3.9 eV and about 4.2 eV. Metals (and metal alloys) that have a work function within this range include but are not limited to: hafnium, zirconium, titanium, tantalum, aluminum, and alloys thereof, such as, hafnium carbide, zirconium carbide, titanium carbide, tantalum carbide, and aluminum carbide. Those skilled in the art will further recognize that the optimal WF for a gate conductor of PFET will be, for example, between about 4.9 eV and about 5.2 eV. Metals (and metal alloys) that have a work function within this range include but are not limited to: ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). Alternatively, the WF metal or metal alloy layer(s) can be metal or metal alloy materials that are selected due to suitability for use in either NFETs or PFETs.

FIG. 7D shows forming a gate conductor 200 over gate metal 198 to complete gate 190. Gate conductor 200 can be, for example, doped polysilicon or any suitable metal or metal alloy fill material including but not limited to: tungsten, a tungsten alloy (e.g., tungsten silicide or titanium tungsten), cobalt, or aluminum. It will be recognized that where gate metal 198 did not complete filling of gate recess(es) 146 in gate region 120, gate conductor 200 will fill any remaining portion of gate recess(es) 146. It will be recognized that a variety of subsequent processing may also be provided in gate region 120, such as but not limited to forming of any ILD necessary to fill between gates 190, forming of gate cut isolations, and forming of a gate cap (not shown) of, for example, a nitride.

It will also be recognized that a variety of subsequent processing may also be provided in both junction region 110 and gate region 120, such as but not limited to forming of any necessary middle-of-line and/or back-end-of-line interconnects to source/drain regions 112, 114 or gates 190. These processes are well known in the field and no further description is required for understanding.

FIGS. 6E and 7D show a structure 90 according to embodiments of the disclosure. Structure 90 includes (first) trench isolation 126 adjacent lower region 124 of fin(s) 102. Trench isolation 126 includes upper portion 152 and lower portion 153. As previously described, upper portion 152 and lower portion 153 include materials of different compositions. For example, upper portion 152 includes a dopant therein, i.e., that creates hardened portions 150, and lower portion 153 is devoid of the dopant. As noted, upper portion 152 is more etch resistant than lower portion 153. As shown in FIG. 7D, structure 90 includes gate recess 146 in trench isolation 126 adjacent gate region 120 of fin(s) 102. Gate recess 146 is at least partially filled with high-K layer 192 and gate metal 198. An inner side of gate recess(es) 146 have the same shape, angle, etc., as of sidewall 156 of fin 102. As shown in FIG. 6E, structure 90 may also include junction recess 144 in (first) trench isolation 126 adjacent junction region 110 of fin(s) 102. Junction recess(es) 144 is/are at least partially filled with low-K layer 174. An inner side of junction recess(es) 144 have the same shape, angle, etc., as of sidewall 156 of fin 102. Second trench isolation 128 (FIG. 1B) does not include any of recess(es) 140. As shown in FIGS. 6A and 7D, gate recess 146 and junction recess 144 both include recess portions on opposing sidewalls 156 of fin(s) in gate region 120 and junction region 110, respectively. In this manner, both sides of fin(s) 102 are constructively taller relative to an uppermost portion of trench isolation 126 adjacent thereto than if recess(es) 146, 144 were not provided.

Structure 90 may also include gate 190 over gate region 120 of fin(s) 102, i.e., providing a FinFET 92. Gate(s) 190 include gate metal conductor 210 (i.e., same layer as gate metal 198) over gate dielectric layer 212 (i.e., same layer as high-K layer 192). Hence, high-K layer 192 in gate recess(es) 146 include a same material as gate dielectric layer 212, and gate metal 198 in gate recess(es) 146 includes a same metal as the gate metal conductor 210. As described relative to FIG. 7B, high-K layer 192 is on opposing sidewalls 194 of gate recess(es) 146 and gate metal 198 is between high-K layer 192 on opposing sidewalls 194 of gate recess(es) 146. In most cases, high-K layer 192 and gate metal 198 fully fill gate recess(es) 146. As described relative to FIG. 6B, in some versions, junction recess(es) 144 may include material 176 in lower portion 162 thereof having a higher thermal conductivity than low-K layer 174 thereover. As described relative to FIG. 2, and as shown in structure 90 in FIGS. 6E and 7D, upper portion 152 of trench isolation 126 has upper surface 158 that is planar, i.e., it is flat with no dips or other irregularities.

FIGS. 6E and 7D also show a FinFET 92 according to embodiments of the disclosure. FinFET 92 is different than LDMOS device 94 in that it does not include second trench isolation 128 (FIG. 1B) and/or certain doping regions 130, 132 used for LDMOS devices 94. FinFET 92 includes semiconductor fin(s) 102 having junction region 110 therein and gate region 120 therein. FinFET 92 also includes (first) trench isolation 126 adjacent lower region 124 of fin(s) 102. Gate recess(es) 146 in trench isolation 126 are adjacent gate region 120 of fin(s) 102 and are at least partially filled with high-K layer 192 and gate metal 198. Trench isolation 126 includes upper portion 152 and lower portion 153 including materials of different compositions. As noted, upper portion 152 may include a dopant, e.g., helium or silicon, therein (creating hardened portion 150 with planar upper surface 158) and lower portion 153 is devoid of the dopant. FinFET 92 also includes junction recess(es) 144 in (first) trench isolation 126 adjacent junction region 110 of fin(s) 102. Junction recess(es) 144 are at least partially filled with low-K layer 174. As shown in FIGS. 6A and 7A, recess(es) 140 (i.e., 144 and 146, respectively) may have upper portion 160 thereof wider than lower portion 162 thereof. In some cases, as described relative to FIG. 4B, recesses 140 can have rounded lower portions 162. With recess(es) 140, as shown in FIGS. 6E and 7D, trench isolation 126 has a first height H1 along sidewall 156 of fin(s) 102, and trench isolation 126 has planar upper surface 158 defining a second height H2 distanced from sidewall 156 of fin(s) 102. In this manner, trench isolations 126 have first height H1 shorter than second height H2. As noted, recess(es) 144, 146 can be precisely sized depending on, for example, fin pitch, to provide constructively taller fin(s) 102 without increasing a footprint of FinFET 92, which improves the performance of FinFET 92.

FinFET 92 also includes gate 190 over gate region 120 of fin(s) 102. Gate(s) 190 include gate metal conductor 210 (i.e., same layer as gate metal 198) over gate dielectric layer 212 (i.e., same layer as high-K layer 192). Hence, high-K layer 192 in gate recess(es) 146 include a same material as gate dielectric layer 212, and gate metal 198 in gate recess(es) 146 includes a same metal as gate metal conductor 210. As described relative to FIG. 7B, high-K layer 192 is on opposing sidewalls 194 of gate recess(es) 146 and gate metal 198 is between high-K layer 192 on opposing sidewalls 194 of gate recess(es) 146. In most cases, high-K layer 192 and gate metal 198 fully fill gate recess(es) 146. As described relative to FIG. 6B, in some versions, junction recess(es) 144 may include material 176 in lower portion 162 thereof having a higher thermal conductivity than low-K layer 174 thereover. As described relative to FIG. 2, and as shown in structure 90 in FIGS. 6E and 7D, upper portion 152 of trench isolation 126 has upper surface 158 that is planar, i.e., it is flat with no dips or other irregularities.

Referring to FIG. 1B, embodiments of the disclosure may also include LDMOS device 94. LDMOS) device 94 includes junction region 110 including a first source/drain region 112, i.e., source region 112, and a second source/drain region 114, i.e., drain region 114, in fin(s) 102. A trench isolation 128 is between first and second source/drain regions 112, 114 in fin(s) 102. LDMOS device 94 includes first doping region 130 about the first source/drain region, i.e., source region 112, that also defines gate region 120 in fin(s) 102. A second doping region 132 is about the second source/drain region, i.e., drain region 114, and also defines drain extension 142 in fin(s) 102 with trench isolation 128. LDMOS device 94 also includes gate 190 over gate region 120 and drain extension 142. Gate region 120, as shown in FIG. 7D, includes gate 190 including high-K layer 192 and gate metal 198. LDMOS device 94 also includes trench isolation 128 adjacent lower region 124 of fin(s) 102 adjacent gate region 120. As shown in FIG. 7D, gate recess 146 is in first trench isolation 126 adjacent gate region 120 and is at least partially filled with high-K layer 192 and gate metal 198. As shown in FIG. 6E, junction recess 144 is in first trench isolation 126 adjacent the junction region 110 (i.e., source region 112 or drain region 114) of fin(s) 102 and is at least partially filled with low-K layer 174. It is emphasized that although not described again herein relative to LDMOS device 94 for brevity sake, any of the embodiments described herein relative to structure 90 or FinFET 92 may be applied to LDMOS device 94.

Embodiments of the disclosure provide various technical and commercial advantages, examples of which are discussed herein. The various structures described herein provide improved device performance by elongating the gate region without increasing a footprint of the device. The structures also reduce sub-fin electrostatic for devices that have both lateral and vertical current flow from drain to source, such as FinFET LDMOS. The LDMOS device also exhibits increased off-state response due to improved gate control at a base of the semiconductor fin.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed.

The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A fin-type field effect transistor (FinFET), comprising:
a semiconductor fin having a junction region therein and a gate region therein;
a trench isolation adjacent a lower region of the semiconductor fin;
a first recess in the trench isolation adjacent the gate region of the semiconductor fin, the first recess at least partially filled with a high dielectric constant (high-K) layer and a gate metal; and
a second recess in the trench isolation adjacent the junction region of the semiconductor fin, the second recess at least partially filled with a low dielectric constant (low-K) layer.

2. The FinFET of claim 1, wherein the second recess includes a material in a lower portion thereof having a higher thermal conductivity than the low-K layer.

3. The FinFET of claim 1, further comprising a gate over the gate region of the semiconductor fin, the gate including a gate metal conductor over a gate dielectric layer, wherein the high-K layer in the first recess includes a same material as the gate dielectric layer, and the gate metal in the first recess includes a same metal as the gate metal conductor.

4. The FinFET of claim 1, wherein the high-K layer is on opposing sidewalls of the first recess and the gate metal is between the high-K layer on the opposing sidewalls of the first recess.

5. The FinFET of claim 4, wherein the high-K layer and the gate metal fully fill the first recess.

6. The FinFET of claim 1, wherein the first recess is narrower at a lower portion than an upper portion thereof.

7. The FinFET of claim 1, wherein the trench isolation includes an upper portion and a lower portion, wherein the upper portion and the lower portion include materials of different compositions.

8. The FinFET of claim 7, wherein the upper portion includes a dopant therein and the lower portion is devoid of the dopant.

9. The FinFET of claim 1, wherein the trench isolation at the first recess has a first height along a sidewall of the semiconductor fin and the trench isolation has an upper surface defining a second height distanced from the sidewall of the semiconductor fin, wherein the first height is shorter than the second height.

10. The FinFET of claim 1, wherein the trench isolation has an upper surface that is planar.

11. A structure for a fin-type field effect transistor (FinFET), comprising:
a trench isolation adjacent a lower region of a semiconductor fin, the trench isolation including an upper portion and a lower portion, wherein the upper portion and the lower portion include materials of different compositions.

12. The structure for a FinFET of claim 11, wherein the upper portion includes a dopant therein and the lower portion is devoid of the dopant.

13. The structure for a FinFET of claim 11, wherein the upper portion is more etch resistant than the lower portion.

14. The structure for a FinFET of claim 11, further comprising a first recess in the trench isolation adjacent a gate region of the semiconductor fin, the first recess at least partially filled with a high dielectric constant (high-K) layer and a gate metal; and a second recess in the trench isolation adjacent a junction region of the semiconductor fin, the second recess at least partially filled with a low dielectric constant (low-K) layer.

15. The structure for a FinFET of claim 14, wherein the first recess and the second recess include recess portions on opposing sides of the semiconductor fin in the gate region and the junction region, respectively.

16. The structure for a FinFET of claim 14, further comprising a gate over the gate region of the semiconductor fin, the gate including a gate metal conductor over a gate dielectric layer, wherein the high-K layer in the first recess includes a same material as the gate dielectric layer, and the gate metal in the first recess includes a same metal as the gate metal conductor.

17. The structure for a FinFET of claim 14, wherein the high-K layer is on opposing sidewalls of the first recess and the gate metal is between the high-K layer on the opposing sidewalls of the first recess, wherein the high-K layer and the gate metal fully fill the first recess.

18. The structure for a FinFET of claim 14, wherein the second recess includes a material in a lower portion thereof having a higher thermal conductivity than the low-K layer.

19. The structure for a FinFET of claim 11, wherein the upper portion of the trench isolation has an upper surface that is planar.

20. A laterally-diffused metal-oxide semiconductor (LDMOS) device, comprising:
a junction region including a first source/drain region and a second source/drain region in a semiconductor fin;
a first trench isolation between the first and second source/drain regions in the semiconductor fin;
a first doping region about the first source/drain region, the first doping region defining a gate region in the semiconductor fin;
a second doping region about the second source/drain region, the second doping region defining a drain extension in the semiconductor fin;
a gate over the gate region and the drain extension, the gate including a high dielectric constant (high-K) layer and a gate metal;
a second trench isolation adjacent a lower region of the semiconductor fin adjacent the gate region;
a first recess in the second trench isolation adjacent the gate region, the first recess at least partially filled with the high-K layer and the gate metal; and
a second recess in the second trench isolation adjacent the junction region of the semiconductor fin, the second recess at least partially filled with a low dielectric constant (low-K) layer.
